(19) United States
(12) Patent Application Publication
(10) Pub. No.: US 2014/0205934 A1
(43) Pub. Date: Jul. 24, 2014

(54) SINGLE RETICLE APPROACH FOR MULTIPLE PATTERNING TECHNOLOGY

(71) Applicant: Xilinx, Inc., (US)

(72) Inventors: Toshiyuki Hisamura, San Jose, CA (US); Michael J. Hart, Palo Alto, CA (US)

(73) Assignee: XILINX, INC., San Jose, CA (US)

(21) Appl. No.: 13/746,017

(22) Filed: Jan. 21, 2013

(51) Int. Cl. G03F 7/20; G03F 1/00

(52) U.S. Cl. CPC G03F 7/2022; G03F 1/00
USPC 430/5; 430/312; 355/18

(57) ABSTRACT

A reticle for multiple patterning a layer of an integrated circuit die includes a first portion with a first layout pattern for multiple patterning the layer of the integrated circuit die, and a second portion with a second layout pattern for multiple patterning the layer of the integrated circuit die. The first layout pattern is different from the second layout pattern.

### TECHNICAL FIELD

This application relates generally to multiple patterning technology, and in particular, to a single reticle approach for multiple patterning technology.

### BACKGROUND

Multiple patterning is a class of technologies for manufacturing integrated circuits that was developed in order to enhance feature density for integrated circuits. As feature sizes continue to decrease, it becomes very difficult to fabricate a single layer on an integrated circuit using a single reticle or mask. Attempting to pattern a large amount of features in close proximity to each other on a single reticle will lead to large inaccuracies in the final pattern of the layer being fabricated on the integrated circuit. This may be caused by the proximity of distances between feature sizes being shorter than the wavelength of light used during the lithography process

The most commonly used approach for multiple patterning is known as double patterning. Double patterning is used to overcome these issues by utilizing two different reticles to fabricate a single layer on an integrated circuit. Each reticle includes features that are far enough in proximity such that the lithography process is unaffected. However, using two different reticles to pattern a single layer has several disadvantages. Having to use two reticles to fabricate a single layer on an integrated circuit leads to greater costs due to the fact that two unique reticles need to be manufactured in order to pattern a single layer. Additionally, the process for fabricating the single layer on the integrated circuit using two reticles is more complex and time consuming than the process for fabricating a layer using a single reticle, because additional steps need to be performed when two reticles are used.

### SUMMARY

A reticle for multiple patterning a layer of an integrated circuit die includes a first portion with a first layout pattern for multiple patterning the layer of the integrated circuit die; and a second portion with a second layout pattern for multiple patterning the layer of the integrated circuit die. The first layout pattern is different from the second layout pattern.

Optionally, the first portion of the reticle may correspond to a first integrated circuit die and the second portion of the reticle may correspond to a second integrated circuit die, the first integrated circuit die and the second integrated circuit die being parts of the integrated circuit die.

Optionally, the reticle may also include a third portion with a third layout pattern for multiple patterning the layer of the integrated circuit die.

Optionally, the third portion of the reticle may correspond to a third integrated circuit die.

Optionally, the first layout pattern and the second layout pattern may be non-combinable on a same portion of the reticle.

Optionally, the reticle may be configured for forming nodes that are 32 nm and smaller.

Optionally, the first portion and the second portion may have different respective numbers of openings.

An apparatus includes the reticle, and a positioner configured to shift the reticle a half reticle step.

A method for performing multiple patterning of a layer of an integrated circuit die with a reticle, includes performing a first lithography process on the layer of the integrated circuit die using the reticle, performing a second lithography process on the layer of the integrated circuit die using the reticle, and etching the layer of the integrated circuit die. The reticle includes a first portion with a first layout pattern for multiple patterning the layer of the integrated circuit die, and a second portion with a second layout pattern for multiple patterning the layer of the integrated circuit die. The first portion of the reticle with the first layout pattern is used to perform the first lithography process, and the second portion of the reticle with the second layout pattern is used to perform the second lithography process.

Optionally, the method may also include performing a bake process between the first lithography process and the second lithography process.

Optionally, the second portion of the reticle with the second layout pattern may be used to perform the first lithography process, and the first portion of the reticle with the first layout pattern may be used to perform the second lithography process.

Optionally, during the first lithography process, the first portion of the reticle may correspond to a first semiconductor die, and the second portion of the reticle may correspond to a second semiconductor die. During the second lithography process, the first portion of the reticle may correspond to the second semiconductor die, and the second portion of the reticle may correspond to the first semiconductor die.

Optionally, the reticle may be shifted a half reticle step between the first lithography process and the second lithography process.

Optionally, the first and second lithography processes may be performed for nodes that are 32 nm and smaller.

Optionally, the method may also include etching the layer of the integrated circuit die after the first lithography process and before the second lithography process.

Optionally, the act of etching the layer of the integrated circuit die may be performed using a dry etch.

Optionally, the act of etching the layer of the integrated circuit die may be performed using a wet etch.

Optionally, the first layout pattern and the second layout pattern may be non-combinable on a same portion of the reticle.

Optionally, the first lithography process may involve performing a first exposure of a photoresist layer on the layer of the integrated circuit die using the reticle, and developing the photoresist layer on the layer of the integrated circuit die.

Optionally, the second lithography process may involve performing a second exposure of the photoresist layer on the layer of the semiconductor wafer using the reticle, and developing the photoresist layer on the layer of the semiconductor wafer.

Other and further aspects and features will be evident from reading the following detailed description.

### BRIEF DESCRIPTION OF THE DRAWINGS

The drawings illustrate the design and utility of some features, in which similar elements are referred to by common reference numerals. These drawings are not necessarily drawn to scale. In order to better appreciate how the above-recited and other advantages and objects are obtained, a more particular description will be rendered, which are illustrated in the accompanying drawings. These drawings are not to be considered limiting in the scope of the claims.

FIG. 1 illustrates a top-view of two reticles used to fabricate a single layer on an integrated circuit die using a double patterning technique.

FIG. 2 is a flow chart illustrating a method for fabricating a single layer on an integrated circuit die using a double patterning technique.

FIGS. 3-1 to 3-7 are side-view schematic diagrams illustrating the double patterning technique for fabricating a single layer on an integrated circuit die of FIG. 2 using the reticles of FIG. 1.

FIGS. 4-1 and 4-2 are top-view schematic diagrams of integrated circuit dies of FIGS. 3-1 to 3-7.

FIG. 5 illustrates a top-view of a single reticle 501 used to fabricate a single layer on an integrated circuit die using a double patterning technique.

FIG. 6 is a flow chart illustrating a method for fabricating a single layer on an integrated circuit die using a double patterning technique with a single reticle.

FIGS. 7-1 to 7-10 are side-view schematic diagrams illustrating the double patterning technique for fabricating a single layer on an integrated circuit of FIG. 6 using the single reticle of FIG. 5.

FIGS. 8-1, 8-2, and 8-3 are top-view schematic diagrams of integrated circuit dies of FIGS. 7-1 to 7-10.

FIG. 9 is a flow chart illustrating a method for fabricating a single layer on an integrated circuit die using a double patterning technique with a single reticle.

FIGS. 10-1 to 10-9 are side-view schematic diagrams illustrating the double patterning technique for fabricating a single layer on an integrated circuit of FIG. 9 using the single reticle of FIG. 5.

FIGS. 11-1 and 11-2 are top-view schematic diagrams of the integrated circuit dies of FIGS. 10-1 to 10-9.

### DETAILED DESCRIPTION

Various features are described hereinafter with reference to the figures. It should be noted that the figures are not drawn to scale, and that the elements of similar structures or functions are represented by like reference numerals throughout the figures. It should be noted that the figures are only intended to facilitate the description. They are not intended as an exhaustive description of the claimed invention or as a limitation on the scope of the claimed invention. In addition, an illustrated item need not have all the aspects or advantages shown. An aspect or an advantage described in conjunction with a particular item is not necessarily limited to that item and can be practiced in any other items even if not so illustrated.

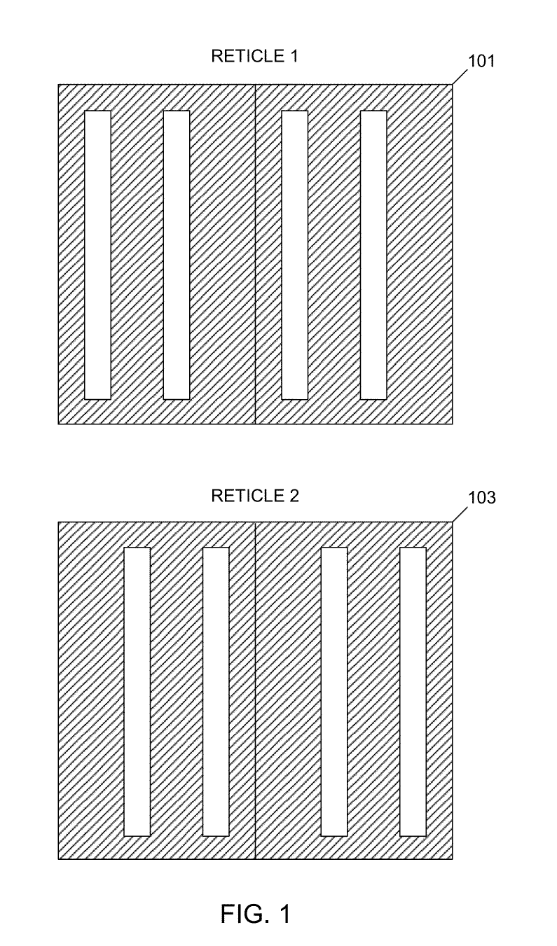

FIG. 1 illustrates a top-view of two reticles (or masks) 101, 103 used to fabricate a single layer on an integrated circuit using a double patterning technique. A first reticle 101 is used to pattern a first layout pattern for the layer on the integrated circuit and the second reticle 103 is used to pattern a second layout pattern on the integrated circuit. As mentioned above, because of the decrease in proximity of distances between feature sizes, the layout pattern of the first reticle 101, and the layout pattern of the second reticle 103 are not combined into a single layout pattern on a single reticle because it will lead to large inaccuracies in the final pattern of the layer being fabricated on the integrated circuit due to the features of the reticle being in closer proximity than the wavelength of light used during the lithography process.

For purposes of illustration, each reticle 101, 103 is used to pattern a layer for two separate, but identical, semiconductor die. As shown in FIG. 1, a first portion (e.g., left partition) of each reticle 101, 103 is used to pattern a layer for a first semiconductor die and a second portion (e.g., right partition) of each reticle 101, 103 is used to pattern a layer for a second semiconductor die. The layout pattern of each portion of each reticle 101,103 is the same.

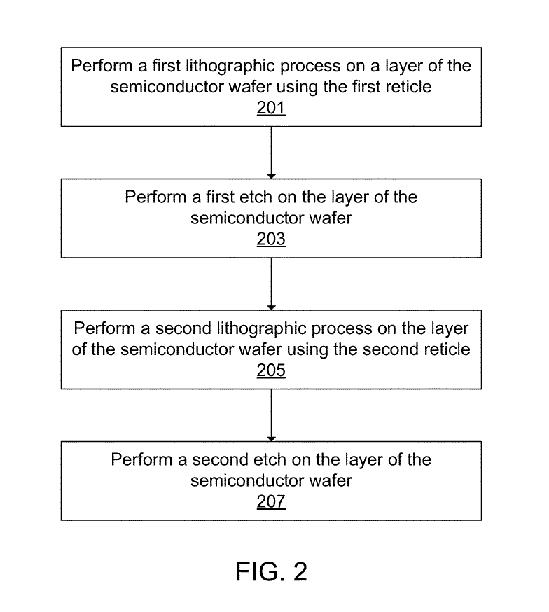

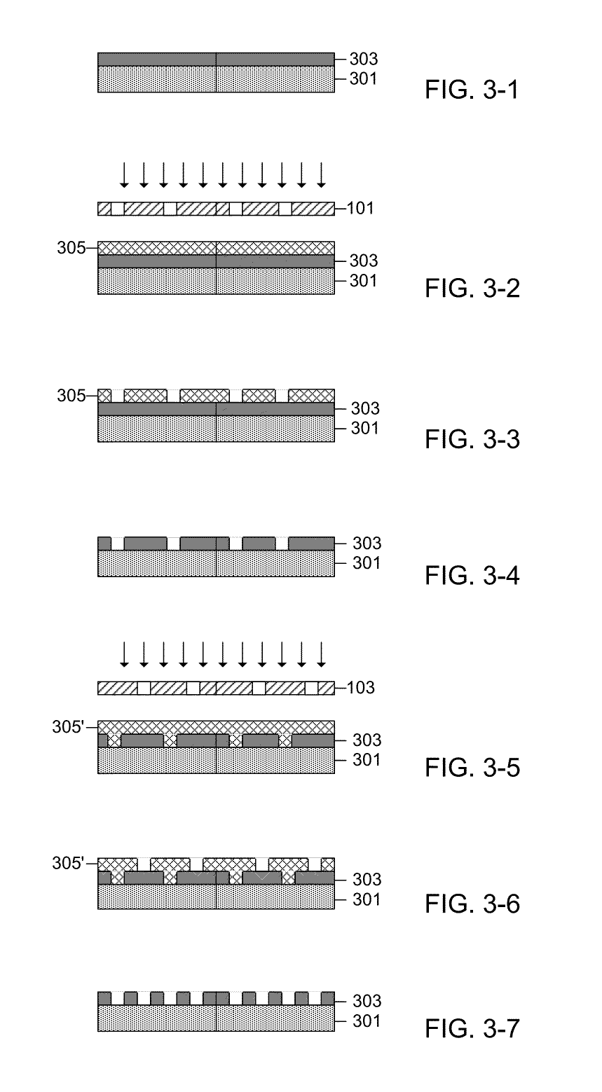

FIG. 2 is a flow chart illustrating a method for fabricating a single layer on an integrated circuit using a double patterning technique. The reticles 101, 103 of FIG. 1 may be used as an example for performing such a double patterning technique.

An unpatterned layer of an integrated circuit die undergoes double patterning to form a patterned layer. A first lithographic process is performed on the layer of the integrated circuit using a first reticle as shown in 201. The first lithographic process may involve forming a first layer of photo-resist on the unpatterned layer, performing an exposure process on the first photoresist layer using the first reticle, and developing the first photoresist layer, such that the first photoresist layer corresponds to the layout pattern of the first reticle. It is important to note that any lithographic process may be performed on the layer of the integrated circuit using the first reticle. For example, a positive photoresist lithographic process or a negative photoresist lithographic process may be performed on the layer of the integrated circuit using the first reticle.

A first etching process may then be performed on the layer of the integrated circuit as shown at 203. Performing an etch using the developed photoresist results in the layer of the integrated circuit having a pattern that corresponds to the first layout pattern of the first reticle. Any etching process may be used. For example, a dry etching technique (such as a plasma etch) or a wet etching technique (such as a chemical etch) may be performed on the layer of the integrated circuit.

After the first etching process, the first photoresist layer may be removed and a second lithographic process is then performed on the layer of the integrated circuit using a second reticle as shown in 205. The second lithographic process may involve forming a second layer of photo-resist on the layer of the integrated circuit, performing an exposure process on the second photoresist layer using the second reticle, and developing the second photoresist layer, such that the second photoresist layer corresponds to the layout pattern of the second reticle. It is important to note that any lithographic process may be performed on the layer of the integrated circuit using the first reticle.

A second etching process may then be performed on the layer of the integrated circuit as shown at 207. Performing a second etching process using the developed photoresist results in the layer of the integrated circuit having a pattern that corresponds to a combination of the first layout pattern of the first reticle and the second layout pattern of the second reticle. Any etching process may be used. For example, a dry etching technique (such as a plasma etch) or a wet etching technique (such as a chemical etch) may be performed on the layer of the integrated circuit. After the second etching process, the first photoresist layer may be removed.

FIGS. 3-1 to 3-7 are side-view schematic diagrams illustrating the double patterning technique of FIG. 2 for fabricating a single layer on an integrated circuit using the reticles of FIG. 1.

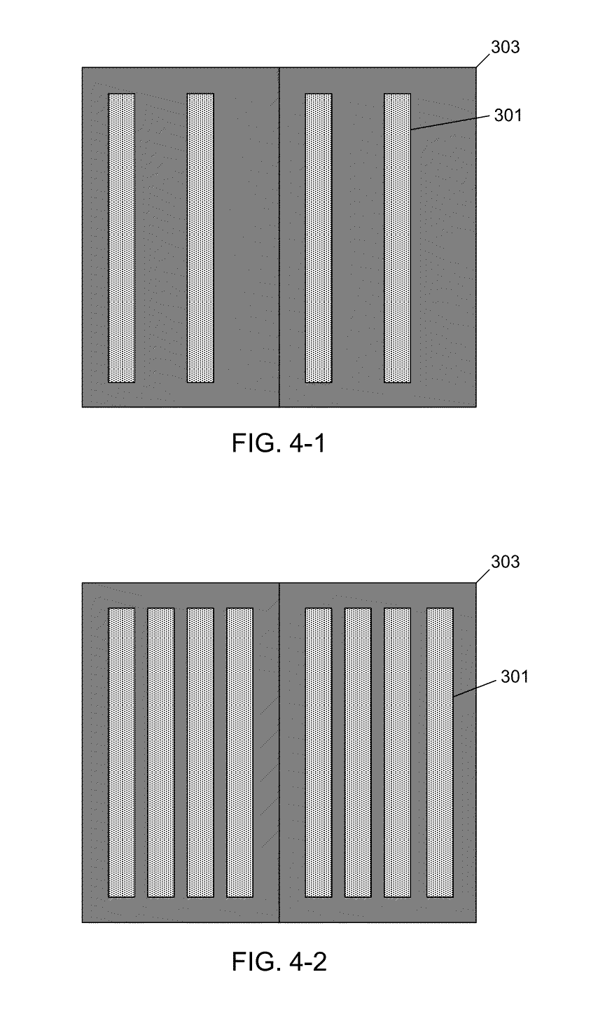

FIG. 3-1 illustrates two integrated circuit dies, each with an unpatterned layer 303 on a surface of a semiconductor wafer 301. It is important to note that while the following description will be made with reference to patterning a single layer that sits on a surface of a semiconductor wafer, any layer of an integrated circuit die may be patterned using the same double patterning technique. The two integrated circuit dies undergo the same fabrication process, as integrated circuits are typically fabricated in a batch process, where a single semiconductor wafer is used to form multiple integrated circuit dies. The vertical line between that runs through the semiconductor wafer 301 and the layer of the integrated circuit 303 denotes the boundary between the two integrated circuit dies. One integrated circuit die sits to the left of the boundary line and another integrated circuit die sits to the right of the boundary line.

The layer 303 of each integrated circuit die undergoes a first lithographic process as illustrated in FIG. 3-2. As mentioned above, a first photoresist layer 305 may be formed on the unpatterned layer 303, followed by an exposure process on the first photoresist layer 305 using the first reticle 101. The first photoresist layer may then be developed, such that the first photoresist layer corresponds to the layout pattern of the first reticle 101 as shown in FIG. 3-3.

A first etching process may then be performed on the layer 303 of the integrated circuit dies using the developed photoresist 305. After etching, the first photoresist layer 303 may be then removed. The first etching process results in the layer 303 of the integrated circuit having a pattern that corresponds to the first layout pattern of the first reticle 101 as illustrated in FIG. 3-4. A top-view of the integrated circuit dies after completing the first etching process is shown in FIG. 4-1. Any etching process may be used. For example, a dry etching technique (such as a plasma etch) or a wet etching technique (such as a chemical etch) may be performed on the layer of the integrated circuit.

A second lithographic process may then be performed on the layer 303 of the integrated circuit dies using a second reticle as shown in FIG. 3-5. The second lithographic process may involve forming a second layer of photo-resist 305′ on the layer 303 of the integrated circuit dies followed by performing an exposure process on the second photoresist layer 305′ using the second reticle 103. The second photoresist layer 305′ may then be developed, such that the second photoresist layer 305′ corresponds to the layout pattern of the second reticle 103 as shown in FIG. 3-6.

A second etching process may then be performed on the layer 303 of the integrated circuit dies using the developed photoresist 305′. After etching, the second photoresist layer 305′ may be then removed. The second etching process results in the layer 303 of the integrated circuit dies each having a pattern that corresponds to a combination of the first layout pattern of the first reticle 101 and the second layout pattern of the second reticle 103 as illustrated in FIG. 3-7. A top-view of the integrated circuit dies after completing the second etching process is shown in FIG. 4-2.

While the double patterning technique illustrated in FIG. 2 and FIGS. 3-1 to 3-7 allow for a layer of the integrated circuit to be formed with very high feature density, the technique suffers from several disadvantages. Using two different reticles to perform double patterning increases design costs, as two unique reticles have to be designed to pattern a single layer of an integrated circuit. Moreover, double patterning requires a first set of process acts that involve using a first reticle to form the first layout pattern in the layer of the integrated circuit, followed by removal of the first reticle, alignment of the second reticle, and a second set of process acts that involve using the second reticle to form the second layout pattern in the layer of the integrated circuit. Having to remove the first reticle and align a second reticle increases cycle-time and complexity. Additionally, critical dimension (CD) and overlay control is complicated by the need to use two different unique reticles.

Utilizing a single reticle for performing a double patterning technique for fabricating a layer of an integrated circuit reduces design costs, cycle-time, and complexity, while also providing improved CD and overlay control.

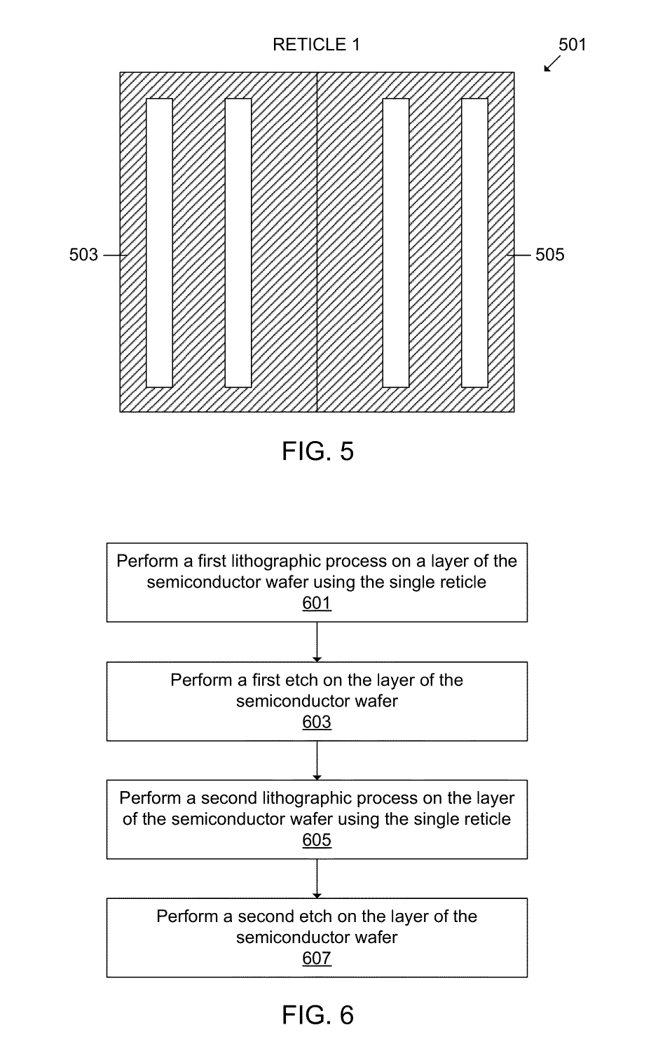

FIG. 5 illustrates a top-view of a single reticle (mask) 501 used to fabricate a single layer on an integrated circuit die using a double patterning technique. The reticle 501 includes a first portion 503 with a first layout pattern and a second portion 505 with a second layout pattern. The first layout pattern is different from the second layout pattern as the first layout pattern and second layout pattern correspond to different portions of an integrated circuit die (e.g., first layout pattern corresponds to a left hand portion of the integrated circuit die and second layout pattern corresponds to a right hand portion of the integrated circuit die. Each portion 501, 503 of the reticle 501 may correspond to a separate integrated circuit die, or may correspond to a separate region of the same integrated circuit die. For purposes of example, the following discussion will be described with reference to each portion of the single reticle corresponding to a separate integrated circuit die. The single reticle 501 is used to pattern the layer of the integrated circuit die such that the layer has a pattern that corresponds to a combination of the first layout pattern and the second layout pattern.

As shown in the figure, the reticle 501 has a symmetrical configuration with respect to a center line between the first portion 503 and the second portion 505. Alternatively, the reticle 501 may have a non-symmetrical configuration. As shown in the illustrated figure, the first layout pattern may be different from the second layout pattern. Alternatively, the first layout pattern may be the same as the second layout pattern. In the illustrated figure, the first portion 503 and the second portion 505 have the same number of openings. Alternatively, the first portion 503 and the second portion 505 may have different respective numbers of openings. The first portion 503 and the second portion 505 may be formed together to provide an unity configuration for the reticle 501. Alternatively, the first portion 503 and the second portion 505 may be mechanically coupled together after they are formed.

FIG. 6 is a flow chart illustrating a method for fabricating a single layer on an integrated circuit die using a double patterning technique with a single reticle. The reticle 501 of FIG. 5 may be used as an example for performing such a double patterning technique.

An unpatterned layer of an integrated circuit die undergoes double patterning to form a patterned layer. A first lithographic process is performed on the layer of the integrated circuit using a first portion of the reticle as shown in 601. The first lithographic process may involve forming a first layer of photo-resist on the unpatterned layer, performing an exposure process on the first photoresist layer using the first portion of the reticle, and developing the first photoresist layer, such that the first photoresist layer corresponds to the layout pattern of the first portion reticle. It is important to note that any lithographic process may be performed on the layer of the integrated circuit using the reticle.

A first etching process may then be performed on the layer of the integrated circuit as shown at 603. Performing an etch using the developed photoresist results in the layer of the integrated circuit having a pattern that corresponds to the first layout pattern of the first portion of the reticle. Any etching process may be used. For example, a dry etching technique (such as a plasma etch) or a wet etching technique (such as a chemical etch) may be performed on the layer of the integrated circuit.

After the first etching process, the first photoresist layer may be removed and a second lithographic process is then performed on the layer of the integrated circuit using a second portion of the reticle as shown in 605. The reticle may simply be shifted a half reticle step in order to align the second portion of the reticle with the layer of the integrated circuit, which will be described in greater detail below. The second lithographic process may involve forming a second layer of photo-resist on the layer of the integrated circuit, performing an exposure process on the second photoresist layer using the second portion of the reticle, and developing the second photoresist layer, such that the second photoresist layer corresponds to the layout pattern of the second portion of the reticle. It is important to note that any lithographic process may be performed on the layer of the integrated circuit using the reticle.

A second etching process may then be performed on the layer of the integrated circuit as shown at 607. Performing a second etching process using the developed photoresist results in the layer of the integrated circuit having a pattern that corresponds to a combination of the first layout pattern of the first portion of the reticle and a second layout pattern of the second portion of the reticle. Any etching process may be used. For example, a dry etching technique (such as a plasma etch) or a wet etching technique (such as a chemical etch) may be performed on the layer of the integrated circuit. After the second etching process, the second photoresist layer may be removed.

The approach for fabricating a single layer on an integrated circuit die described in FIG. 6 may also be referred to as a litho-etch-litho-etch process.

FIGS. 7-1 to 7-10 are side-view schematic diagrams illustrating the double patterning technique of FIG. 6 for fabricating a single layer on an integrated circuit using the single reticle 501 of FIG. 5.

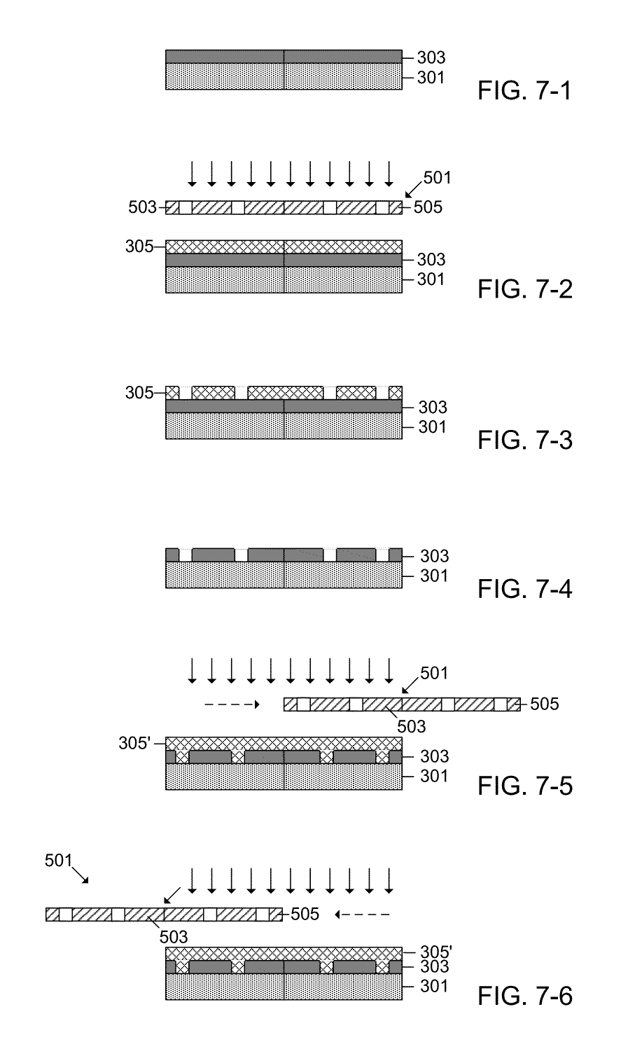

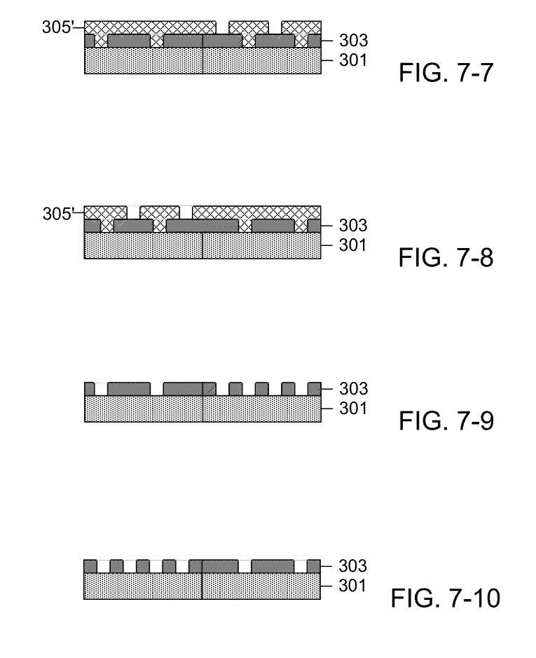

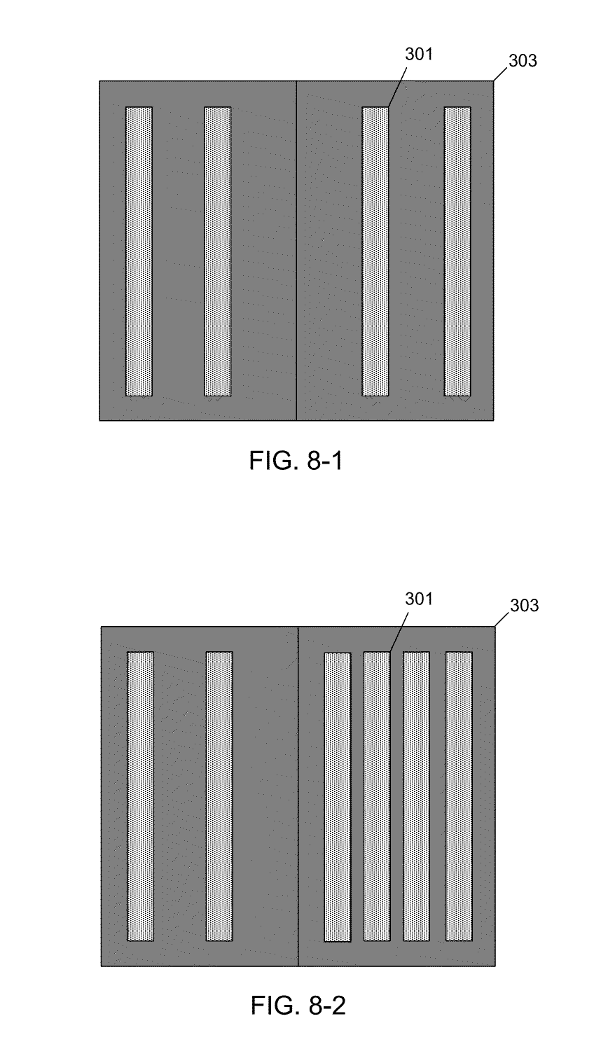

FIG. 7-1 illustrates two integrated circuit dies, each with an unpatterned layer 303 on a surface of a semiconductor wafer 301. It is important to note that while the following description will be made with reference to patterning a single layer that sits on a surface of a semiconductor wafer, any layer of an integrated circuit may be patterned using the same double patterning technique. The vertical line between that runs through the semiconductor wafer 301 and the layer of the integrated circuit 303 denotes the boundary between the two integrated circuit dies. One integrated circuit die sits to the left of the boundary line and another integrated circuit die sits to the right of the boundary line.

The layer 303 of each integrated circuit die undergoes a first lithographic process as illustrated in FIG. 7-2. A first photoresist layer 305 may be first formed on the unpatterned layer 303. An exposure process on the first photoresist layer 305 using the reticle 501 may then be performed. As mentioned above, the reticle 501 includes a first portion 503 with a first layout pattern and a second portion 505 with a second layout pattern. Thus, during the first lithographic process, one integrated circuit die (e.g., integrated circuit die on the left) undergoes an exposure process using the first portion 503 of the reticle 501 and the other integrated circuit die (e.g., integrated circuit die on the right) undergoes an exposure process using the second portion 505 of the reticle 501. The first photoresist layer 305 may then be developed. After undergoing development, the pattern of the first photoresist layer 305 residing on the integrated circuit die (e.g., integrated circuit die on the left) that undergoes the exposure process using the first portion 503 of the reticle 501 corresponds to the first layout pattern of the first portion 503 of the reticle 501 as shown in FIG. 7-3. Similarly, after undergoing development, the pattern of the first photoresist layer residing on the integrated circuit die (e.g., integrated circuit die on the right) that undergoes exposure using the second portion 505 of the reticle 501 corresponds to the second layout pattern of the second portion 505 of the reticle 501 also shown in FIG. 7-3.

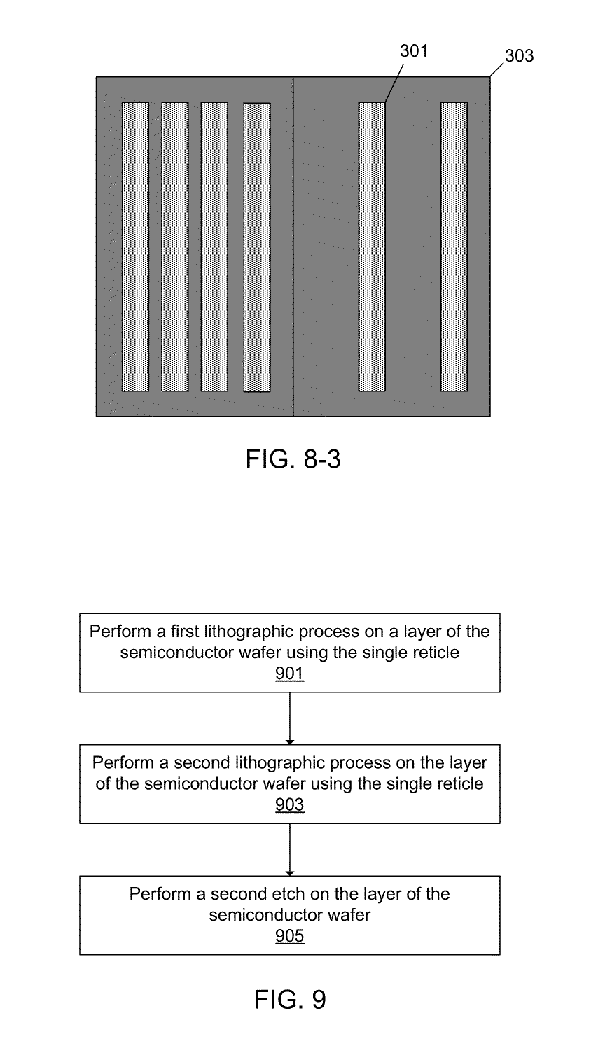

A first etching process may then be performed on the layer 303 of the integrated circuit dies using the developed photoresist 305. After etching, the first photoresist layer 303 may be then removed. The first etching process results in the layer 303 of the integrated circuit die (e.g., integrated circuit die on the left) that undergoes a lithographic process using the first portion 503 of the reticle 501 having a pattern that corresponds to the first layout pattern of the first portion 503 of the reticle 501 as shown in FIG. 7-4. Similarly, the first etching process results in the layer 303 of the integrated circuit die (e.g., integrated circuit die on the right) that undergoes a lithographic process using the second portion 505 of the reticle 501 having a pattern that corresponds to the second layout pattern of the second portion 505 of the reticle 501 as shown in FIG. 7-4. A top-view of the integrated circuit dies after completing the first etching process is shown in FIG. 8-1. Any etching process may be used. For example, a dry etching technique (such as a plasma etch) or a wet etching technique (such as a chemical etch) may be performed on the layer of the integrated circuit.

After the first etching process, a second photoresist layer 305′ may be formed on the layer 303 of the integrated circuit dies, like that shown in FIG. 7-5.

Next, the reticle 501 may be repositioned such that the integrated circuit die that underwent a first lithographic process using the second portion 505 of the reticle 501 now undergoes a second lithographic process using the first portion 503 of the reticle 501 as illustrated in FIG. 7-5. Alternatively, the reticle 501 may be repositioned such that the integrated circuit die that underwent a first lithographic process using the first portion 503 of the reticle 501 now undergoes a second lithographic process using the second portion 505 of the reticle 501 as illustrated in FIG. 7-6. In some cases, this may be accomplished by moving the reticle 501 a half reticle step (e.g., using a mechanical positioner) as illustrated in FIG. 7-5 and FIG. 7-6. By shifting the reticle 501 a half reticle step, an integrated circuit die that was previously associated with a first portion 503 of the reticle 501 is now associated with a second portion 505 of the reticle 501, or vice versa.

FIG. 7-5 illustrates the reticle 501 being shifted a half reticle step to the right such that the integrated circuit die (e.g., the integrated circuit die on the right) may be additionally patterned with a different layout pattern of the reticle 501. While not illustrated, an additional identical reticle may be provided to pattern a pair of integrated circuit dies adjacent to (to the left of) the pair of integrated circuit dies illustrated in FIG. 7-5, and may be shifted a half reticle to the right such that the second portion with the second layout pattern of the additional reticle may now correspond to the integrated circuit die (e.g., the integrated circuit die on the left in FIG. 7-5). In this way, both integrated circuit dies may undergo a second lithographic process to form their respective layout patterns simultaneously.

Similarly, FIG. 7-6 illustrates the reticle 501 being shifted a half reticle step to the left such that the integrated circuit die (e.g., the integrated circuit die on the left) may be additionally patterned with a different layout pattern of the reticle 501. Also while not illustrated, an additional identical reticle may be provided to pattern a pair of integrated circuit dies adjacent to (to the right of) the pair of integrated circuit dies illustrated in FIG. 7-6, and may be shifted a half reticle to the left such that the first portion with the first layout pattern of the additional reticle may now correspond to the integrated circuit die (e.g., the integrated circuit die on the right in FIG. 7-6). In this way, both integrated circuit dies may undergo a second lithographic process to form their respective layout patterns simultaneously.

After the reticle 501 has been shifted a half reticle step (either to the right or to the left), an exposure process on the second photoresist layer 305′ using the reticle 501 may then be performed. In the situation in which the reticle 501 is shifted to the right, like that shown in FIG. 7-5, during the second lithographic process, the integrated circuit die that previously underwent a first lithographic process using the second portion 505 of the reticle 501 now undergoes an exposure process using the first portion 503 of the reticle 501. Alternatively, if the reticle 501 is shifted to the left, like that shown in FIG. 7-6, the integrated circuit die that previously underwent a first lithographic process using the first portion 503 of the reticle now undergoes an exposure process using the second portion 505 of the reticle 501.

FIG. 7-7 corresponds to the situation in which the reticle 501 has been moved to the right (like that shown in FIG. 7-5). As shown in FIG. 7-7, after undergoing development, the pattern of the second photoresist layer 305′ residing on the integrated circuit die (e.g., integrated circuit die on the right) that undergoes exposure using the first portion 503 of the reticle 501 corresponds to the second layout pattern of the second portion 503 of the reticle 501. A second etching process may then be performed on the layer 303 of the integrated circuit die (e.g., integrated circuit die on the right) using the developed photoresist 305′. After etching, the second photoresist layer 305′ may be then removed. The second etching process results in the layer 303 of the integrated circuit die (e.g., integrated circuit die on the right) having a pattern that corresponds to a combination of the first layout pattern of the first portion 503 of the reticle 501 and the second layout pattern of the second portion 505 of the reticle 501 as illustrated in FIG. 7-9. A top-view of the integrated circuit dies after completing the second etching process is shown in FIG. 8-2.

As discussed, if an additional reticle is provided to the left of the reticle 501 in FIG. 7-5, the additional reticle may be shifted to the right side together with the reticle 501. Such configuration would result in patterning the left portion of the second photoresist layer 305′ in FIG. 7-7, so that the left portion of the second photoresist layer 305′ would look like that in the right portion of the second photoresist layer 305′ shown in FIG. 7-7. After etching, the left portion of the layer 303 (instead of that shown in FIG. 7-9) would have the same configuration as that of the right portion of the layer 303 shown in FIG. 7-9.

FIG. 7-8 corresponds to the situation in which the reticle 501 has been moved to the left (like that shown in FIG. 7-6). As shown in FIG. 7-8, after undergoing development, the pattern of the second photoresist layer 305′ residing on the integrated circuit die (e.g., integrated circuit die on left) that undergoes the exposure process using the second portion 505 of the reticle 501 corresponds to the second layout pattern of the second portion 505 of the reticle 501. A second etching process may then be performed on the layer 303 of the integrated circuit die (e.g., integrated circuit die on the left) using the developed photoresist 305′. After etching, the second photoresist layer 305′ may be then removed. The second etching process results in the layer 303 of the integrated circuit die (e.g., integrated circuit die on the left) having a pattern that corresponds to a combination of the first layout pattern of the first portion 503 of the reticle 501 and the second layout pattern of the second portion 505 of the reticle 501 as illustrated in FIG. 7-10. A top-view of the integrated circuit dies after completing the second etching process is shown in FIG. 8-3.

As discussed, if an additional reticle is provided to the right of the reticle 501 in FIG. 7-6, the additional reticle may be shifted to the left side together with the reticle 501. Such configuration would result in patterning the right portion of the second photoresist layer 305′ in FIG. 7-8, so that the right portion of the second photoresist layer 305′ would look like that in the left portion of the second photoresist layer 305′ shown in FIG. 7-8. After etching, the right portion of the layer 303 (instead of that shown in FIG. 7-10) would have the same configuration as that of the left portion of the layer 303 shown in FIG. 7-10.

By utilizing a single reticle to fabricate a layer on an integrated circuit rather than two unique reticles, several of the disadvantages described above may be reduced. For one, reticle costs are reduced as only a single reticle is required in order to pattern a single layer of an integrated circuit using double patterning technology as opposed to the conventional approach which requires two unique sets of reticles. Additionally, cycle-time and complexity is reduced as the step of removing the first reticle and aligning the second reticle is replaced by a simple shift or repositioning of a single reticle. Furthermore, CD and overlay control is improved as only a single reticle is needed to perform the double patterning technique.

The method for fabricating a single layer on an integrated circuit die using a double patterning technique with a single reticle can be further simplified by using a single etch process with two lithographic processes. FIG. 9 is a flow chart illustrating a method for fabricating a single layer on an integrated circuit die using a double patterning technique with a single reticle. The method of FIG. 9 uses a single etch process with two lithographic processes rather than the litho-etch-litho-etch method described in FIG. 6. The approach for fabricating a single layer on an integrated circuit die described in FIG. 9 may also be referred to as a litho-litho-etch process.

An unpatterned layer of an integrated circuit die undergoes double patterning to form a patterned layer. A first lithographic process is performed on the layer of the integrated circuit using a first portion of the reticle as shown in 901. The first lithographic process may involve forming a first layer of photo-resist on the unpatterned layer, performing an exposure process on the first photoresist layer using the first portion of the first reticle, and developing the first photoresist layer, such that the first photoresist layer corresponds to the layout pattern of the first portion of the reticle. It is important to note that any lithographic process may be performed on the layer of the integrated circuit using the reticle.

A second lithographic process may then be performed on the layer of the integrated circuit using a second portion of the reticle as shown in 903. The reticle may simply be shifted a half reticle step in order to align the second portion of the reticle with the layer of the integrated circuit, which will be described in greater detail below. The second lithographic process may involve performing an exposure process on the first photoresist layer using the second portion of the reticle, and again developing the first photoresist layer, such that the first photoresist layer corresponds to a combination of the layout pattern of the first portion of the reticle and the layout pattern of the second portion of the reticle. Optionally, a bake action may be performed between the first lithographic process and the second lithographic process to fix the pattern of the first photoresist layer after the first lithographic process. For example, in a resist freezing-free litho-litho-etch process (which may involve additional chemicals or additional steps to prevent unwanted mixing or reactivation in the first photoresist layer in the second lithographic process), a bake action may be performed. This bake action may be performed in-situ without having to remove the integrated circuit from its processing area.

An etching process may then be performed on the layer of the integrated circuit as shown at 905. Performing an etching process using the developed photoresist results in the layer of the integrated circuit having a pattern that corresponds to a combination of the first layout pattern of the first portion of the reticle and a second layout pattern of the second portion of the reticle. Any etching process may be used. For example, a dry etching technique (such as a plasma etch) or a wet etching technique (such as a chemical etch) may be performed on the layer of the integrated circuit. After the second etching process, the second photoresist layer may be removed.

FIGS. 10-1 to 10-9 are side-view schematic diagrams illustrating the double patterning technique of FIG. 9 for fabricating a single layer on an integrated circuit using the single reticle 501 of FIG. 5.

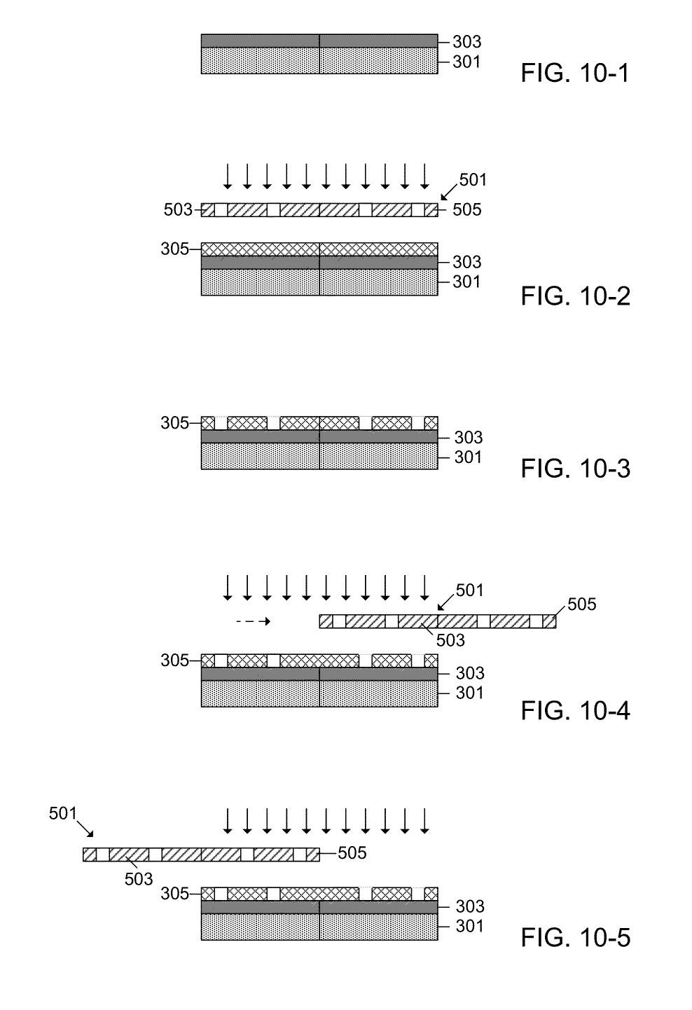

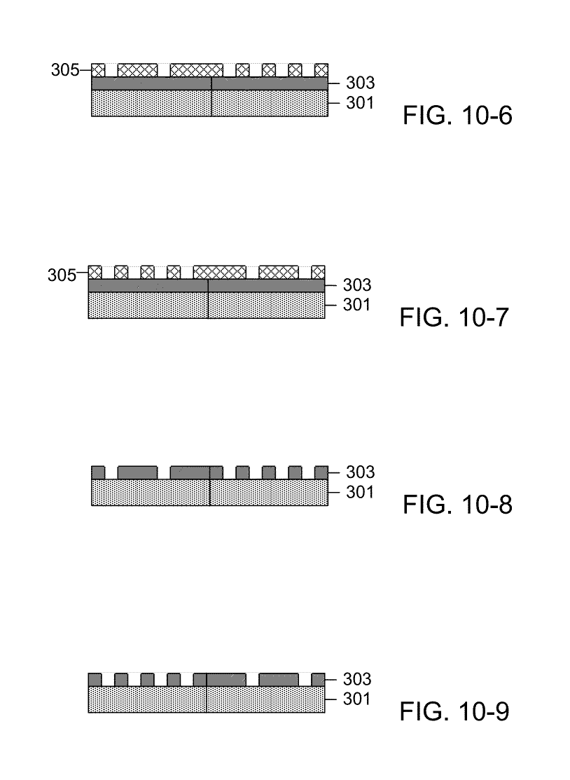

FIG. 10-1 illustrates two integrated circuit dies, each with an unpatterned layer 303 on a surface of a semiconductor wafer 301. It is important to note that while the following description will be made with reference to patterning a single layer that sits on a surface of a semiconductor wafer, any layer of an integrated circuit may be patterned using the same double patterning technique. The vertical line between that runs through the semiconductor wafer 301 and the layer of the integrated circuit 303 denotes the boundary between the two integrated circuit dies. One integrated circuit die sits to the left of the boundary line and another integrated circuit die sits to the right of the boundary line.

The layer 303 of each integrated circuit die undergoes a first lithographic process as illustrated in FIG. 10-2. A first photoresist layer 305 may be first formed on the unpatterned layer 303. An exposure process on the first photoresist layer 305 using the reticle 501 may then be performed. As mentioned above, the reticle 501 includes a first portion 503 with a first layout pattern and a second portion 505 with a second layout pattern. Thus, during the first lithographic process, one integrated circuit (e.g. integrated circuit die on the left) die undergoes an exposure process using the first portion 503 of the reticle 501 and the other integrated circuit die (e.g., integrated circuit die on the right) undergoes an exposure process using the second portion 505 of the reticle 501. The first photoresist layer may then be developed. After undergoing development, the pattern of the first photoresist layer residing on the integrated circuit die (e.g., integrated circuit die on the left) that undergoes the exposure process using the first portion 503 of the reticle 505 corresponds to the first layout pattern of the first portion 503 of the reticle 505 as shown in FIG. 10-3. Similarly, after undergoing development, the pattern of the first photoresist layer residing on the integrated circuit die (e.g., integrated circuit die on the right) that undergoes exposure using the second 505 portion of the reticle 501 corresponds to the second layout pattern of the second 505 portion of the reticle 501 also shown in FIG. 10-3.

After the first lithographic process, the reticle 501 may be repositioned such that the integrated circuit die (e.g., integrated circuit die on the right) that underwent a first lithographic process using the second portion 505 of the reticle 501 now undergoes a second lithographic process using the first portion 503 of the reticle 501 as illustrated in FIG. 10-4.

Alternatively, after the first lithographic process, the reticle 501 may be repositioned such that the integrated circuit die (e.g., integrated circuit die on the left) that underwent a first lithographic process using the first portion 503 of the reticle 501 now undergoes a second lithographic process using the second portion 505 of the reticle 501, as illustrated in FIG. 10-5.

In some cases, the above may be accomplished by moving the reticle 501 a half reticle step to the right as illustrated in FIG. 10-4, or a half step to the left as illustrated in FIG. 10-5. By shifting the reticle 501 a half reticle step, an integrated circuit die that was previously associated with a first portion 503 of the reticle 501 is now associated with a second portion 505 of the reticle 501, or vice versa.

FIG. 10-4 illustrates the reticle 501 being shifted a half reticle step to the right such that the integrated circuit die (e.g., the integrated circuit die on the right) may be additionally patterned with a different layout pattern of the same reticle 501. While not illustrated, an additional identical reticle (being used to pattern a pair of integrated circuit dies adjacent to the pair of integrated circuit dies illustrated in FIG. 10-4) may also be provided, and may be shifted a half reticle step to the right together with the reticle 501 such that the second portion with the second layout pattern of the additional reticle may now correspond to the integrated circuit die (e.g., the integrated circuit on the left in FIG. 10-4). In this way, both integrated circuit dies in FIG. 10-4 may undergo a second lithographic process to form their respective layout patterns simultaneously.

Similarly, FIG. 10-5 illustrates the reticle 501 being shifted a half reticle to the left step such that the integrated circuit die (e.g., the integrated circuit die on the left) may be additionally patterned with a different layout pattern of the reticle 501. Also while not illustrated, an additional identical reticle (being used to pattern a pair of integrated circuit dies adjacent to the pair of integrated circuit dies illustrated in FIG. 10-5) may also be provided, and may be shifted a half reticle step to the left together with the reticle 501 such that the first portion with the first layout pattern of the additional reticle may now correspond to the integrated circuit die (e.g., the integrated circuit on the right in FIG. 10-5). In this way, both integrated circuit dies in FIG. 10-5 may undergo a second lithographic process to form their respective layout patterns simultaneously.

Optionally, a bake action may be performed between the first lithographic process and the second lithographic process to fix the pattern of the first photoresist layer after the first lithographic process. For example, in a resist freezing-free litho-litho-etch process (which may involve additional chemicals or additional steps to prevent unwanted mixing or reactivation in the first photoresist layer at the second lithographic process), a bake action may be performed. This bake action may be performed in-situ without having to remove the integrated circuit from its processing area.

After the reticle 501 has been positioned (either to the right or to the left), an exposure process on the first photoresist layer 305 using the reticle 501 may then be performed. In FIG. 10-4, during the second lithographic process, the integrated circuit die that previously underwent a first lithographic process using the second portion 505 of the reticle 501 now undergoes an exposure process using the first portion 503 of the reticle 501. Similarly, in FIG. 10-5, the integrated circuit die that previously underwent a first lithographic process using the first portion 503 of the reticle 501 now undergoes an exposure process using the second portion 505 of the reticle 501. The photoresist layer 305 may then be developed.

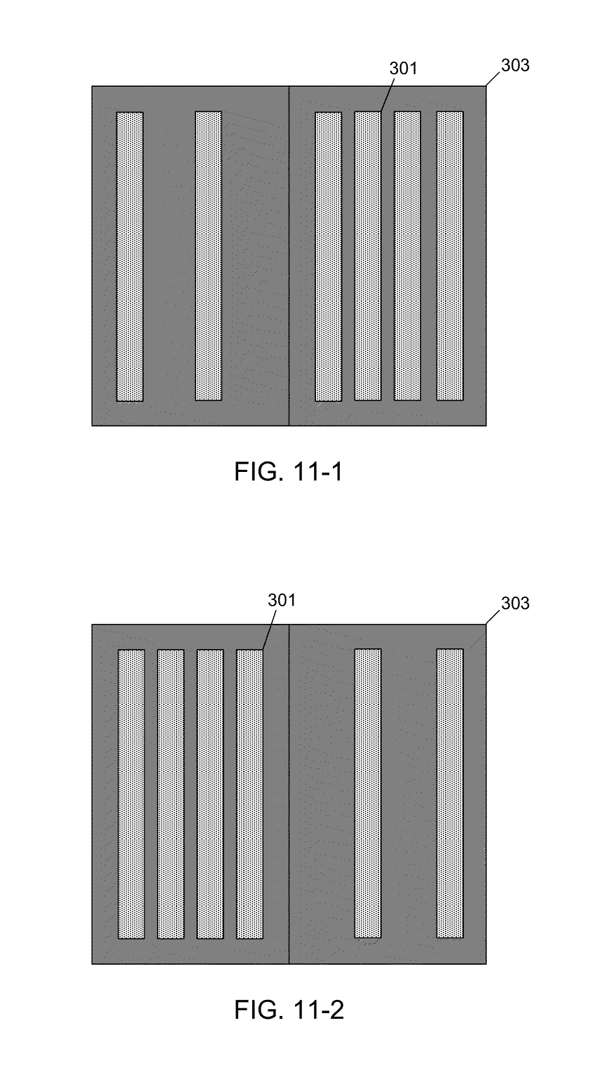

After the exposure process, the photoresist layer 305 is then developed. FIG. 10-6 corresponds to the situation in which the reticle 501 was shifted to the right (like that shown in FIG. 10-4). As shown in FIG. 10-6, after undergoing development, the pattern of the photoresist layer 305 residing on the integrated circuit die (e.g., integrated circuit die on the right) that undergoes exposure using the first portion 503 of the reticle 501 corresponds to a combination of the first layout pattern of the first portion 503 of the reticle 501 and the second layout pattern of the second portion 505 of the reticle 501. An etching process may then be performed on the layer 303 of the integrated circuit dies using the developed photoresist 305. After etching, the photoresist layer 305 may be then removed. The etching process results in the layer 303 of the integrated circuit die (e.g., integrated circuit die on the right) having a pattern that corresponds to a combination of the first layout pattern of the first portion 503 of the reticle 501 and the second layout pattern of the second portion 505 of the reticle 501 as illustrated in FIG. 10-8. A top-view of the integrated circuit dies after completing the etching process is shown in FIG. 11-1.

As similarly discussed, if an additional reticle is provided to the left of the reticle 501 in FIG. 10-4, the additional reticle may be shifted to the right side together with the reticle 501. Such configuration would result in patterning the left portion of the photoresist layer 305 in FIG. 10-6, so that the left portion of the photoresist layer 305 would look like that in the right portion of the photoresist layer 305 shown in FIG. 10-6. After etching, the left portion of the layer 303 (instead of that shown in FIG. 10-8) would have the same configuration as that of the right portion of the layer 303 shown in FIG. 10-8.

FIG. 10-7 corresponds to the situation in which the reticle 501 was alternatively shifted to the left (like that shown in FIG. 10-5). As shown in FIG. 10-7, after undergoing development, the pattern of the photoresist layer 305 residing on the integrated circuit die (e.g., integrated circuit die on the left) that undergoes exposure using the second portion 505 of the reticle 501 corresponds to a combination of the first layout pattern of the first portion 503 of the reticle 501 and the second layout pattern of the second portion 505 of the reticle 501. An etching process may then be performed on the layer 303 of the integrated circuit dies using the developed photoresist 305. After etching, the photoresist layer 305 may be then removed. The etching process results in the layer 303 of the integrated circuit die (e.g., integrated circuit die on the left) having a pattern that corresponds to a combination of the first layout pattern of the first portion 503 of the reticle 501 and the second layout pattern of the second portion 505 of the reticle 501 as illustrated in FIG. 10-9. A top-view of the integrated circuit dies after completing the etching process is shown in FIG. 11-2.

As similarly discussed, if an additional reticle is provided to the right of the reticle 501 in FIG. 10-5, the additional reticle may be shifted to the left side together with the reticle 501. Such configuration would result in patterning the right portion of the photoresist layer 305 in FIG. 10-7, so that the right portion of the photoresist layer 305 would look like that in the left portion of the photoresist layer 305 shown in FIG. 10-7. After etching, the right portion of the layer 303 (instead of that shown in FIG. 10-9) would have the same configuration as that of the left portion of the layer 303 shown in FIG. 10-9.

By utilizing only a single etch, the cycle-time and complexity associated with the fabrication process may be further simplified.

While the above description has been described with reference to fabricating a single layer on an integrated circuit using single-reticle, double patterning technique, one ordinarily skilled in the art will recognize that the single-reticle may be extended for use with various multiple patterning techniques. For example, a triple-patterning technique may be used with a single reticle that includes a first portion having a first layout pattern, a second portion having a second layout pattern, and a third portion having a third layout pattern. The first, second, and third layout patterns may be the same, or may be different from each other. Three semiconductor dies may be patterned using the single reticle using a litho-etch-litho-etch-litho-etch approach similar to the litho-etch-litho-etch approach described above in FIG. 6 and FIGS. 7-1 to 7-10, or using a litho-litho-litho-etch approach similar to the litho-litho-etch approach described above in FIG. 9 and FIGS. 10-1 to 10-9. In a manner similar to that described above in FIGS. 6 and 9, each semiconductor die may undergo consecutive lithographic processes using the different layout patterns of the reticle.

Although particular features have been shown and described, it will be understood that they are not intended to limit the claimed invention, and it will be made obvious to those skilled in the art that various changes and modifications may be made without departing from the spirit and scope of the claimed invention. The specification and drawings are, accordingly, to be regarded in an illustrative rather than restrictive sense. The claimed invention is intended to cover alternatives, modifications, and equivalents.

1. A reticle for multiple patterning a layer of an integrated circuit die, comprising:
a first portion with a first layout pattern for multiple patterning the layer of the integrated circuit die; and
a second portion with a second layout pattern for multiple patterning the layer of the integrated circuit die, wherein the first layout pattern is different from the second layout pattern.

2. The reticle of claim 1, wherein the first portion of the reticle corresponds to a first integrated circuit die and the second portion of the reticle corresponds to a second integrated circuit die, the first integrated circuit die and the second integrated circuit die being parts of the integrated circuit die.

3. The reticle of claim 2, further comprising a third portion with a third layout pattern for multiple patterning the layer of the integrated circuit die.

4. The reticle of claim 3, wherein the third portion of the reticle corresponds to a third integrated circuit die.

5. The reticle of claim 1, wherein the first layout pattern and the second layout pattern are non-combinable on a same portion of the reticle.

6. The reticle of claim 1, wherein the reticle is configured for forming nodes that are 32 nm and smaller.

7. The reticle of claim 1, wherein the first portion and the second portion have different respective numbers of openings.

8. An apparatus comprising the reticle of claim 1, and a positioner configured to shift the reticle a half reticle step.

9. A method for performing multiple patterning of a layer of an integrated circuit die with a reticle, comprising:
performing a first lithography process on the layer of the integrated circuit die using the reticle;
performing a second lithography process on the layer of the integrated circuit die using the reticle; and
etching the layer of the integrated circuit die;
wherein the reticle includes a first portion with a first layout pattern for multiple patterning the layer of the integrated circuit die, and a second portion with a second layout pattern for multiple patterning the layer of the integrated circuit die; and
wherein the first portion of the reticle with the first layout pattern is used to perform the first lithography process, and the second portion of the reticle with the second layout pattern is used to perform the second lithography process.

10. The method of claim 9, further comprising performing a bake process between the first lithography process and the second lithography process.

11. The method of claim 9, wherein:
the second portion of the reticle with the second layout pattern is used to perform the first lithography process; and
the first portion of the reticle with the first layout pattern is used to perform the second lithography process.

12. The method of claim 9, wherein:
during the first lithography process, the first portion of the reticle corresponds to a first semiconductor die, and the second portion of the reticle corresponds to a second semiconductor die; and
during the second lithography process, the first portion of the reticle corresponds to the second semiconductor die, and the second portion of the reticle corresponds to the first semiconductor die.

13. The method of claim 9, wherein the reticle is shifted a half reticle step between the first lithography process and the second lithography process.

14. The method of claim 9, wherein the first and second lithography processes are performed for nodes that are 32 nm and smaller.

15. The method of claim 9, further comprising etching the layer of the integrated circuit die after the first lithography process and before the second lithography process.

16. The method of claim 9, wherein the act of etching the layer of the integrated circuit die is performed using a dry etch.

17. The method of claim 9, wherein the act of etching the layer of the integrated circuit die is performed using a wet etch.

18. The method of claim 9, wherein the first layout pattern and the second layout pattern are non-combinable on a same portion of the reticle.

19. The method of claim 9, wherein the first lithography process comprises:
performing a first exposure of a photoresist layer on the layer of the integrated circuit die using the reticle; and
developing the photoresist layer on the layer of the integrated circuit die.

20. The method of claim 19, wherein the second lithography process comprises
performing a second exposure of the photoresist layer on the layer of the semiconductor wafer using the reticle; and
developing the photoresist layer on the layer of the semiconductor wafer.
